(19) United States
(12) Patent Application Publication
(10) Pub. No.: US 2026/0356086 A1
(43) Pub. Date: Nov. 12, 2026

(54) METHOD AND DEVICE FOR APPLYING ADHESIVE TO SOLAR ELEMENTS, METHOD FOR PRODUCING SOLAR MODULES AND SOLAR MODULE MANUFACTURING DEVICE

(71) Applicant: M10 Solar Equipment GmbH, Freiburg (DE)

(72) Inventors: Dominique JEHL, Rhinau (FR); Michael FEHRENBACH, Waldkirch (DE); Joachim KIEFER, Schönau im Schwarzwald (DE); Frank BAUMANN, Kappel-Grafenhausen (DE)

(73) Assignee: M10 Solar Equipment GmbH, Freiburg (DE)

(21) Appl. No.: 19/120,277

(22) PCT Filed: Oct. 9, 2023
(86) PCT No.: PCT/EP2023/077874

§ 371 Date: Apr. 11, 2025

(30) Foreign Application Priority Data
Oct. 13, 2022 (DE) 10 2022 126 711.3

(51) Int. Cl. B32B 37/12

(52) U.S. Cl. CPC B32B 37/1284; B32B 2457/12

(57) ABSTRACT

A method for applying, in particular electrically conductive, adhesive to solar elements (2), wherein a solar element (2) is moved with a workpiece carrier (5) of a feed device (7) in a transfer movement past a dispensing nozzle (4) of a dispensing device (3) for adhesive and adhesive is applied to the solar element (2) in the process. Before the adhesive is applied, a setting movement is carried out transversely to the transfer movement, thereby setting a defined distance at which the solar element (2) is then moved past the dispensing nozzle (4) for the application of adhesive.

### CROSS-REFERENCE TO RELATED APPLICATIONS

This application is a 371 National Phase of PCT/EP2023/077874, filed Oct. 9, 2023, which claims priority from German Patent Application No. 10 2022 126 711.3, filed Oct. 13, 2022, both of which are incorporated herein by reference as if fully set forth.

### TECHNICAL FIELD

The invention relates to a method and a device for applying, in particular electrically conductive, adhesive to solar elements. Such methods and devices can be used in the production of solar modules.

### BACKGROUND

Various approaches are known for manufacturing solar modules from solar elements, for example from solar cells and/or solar cell strips and/or solar cell shingles.

It is provided in one approach that the solar elements are glued to one another when assembling the solar module. Adhesive, in particular electrically conductive adhesive, is used for this purpose. With the help of the electrically conductive adhesive, it is possible to electrically connect the poles of solar elements that overlap each other in the solar module, at least partially, and thus to establish an electrical and at the same time a mechanical connection between the overlapping solar elements of the solar module. The solar elements can be arranged in rows in the solar module, with adjacent rows of solar elements in the solar module overlapping each other and being glued together. If adjacent rows in the solar module are arranged offset to each other, a so-called shingled matrix solar module can be produced.

In a solar module constructed from pairs of mutually overlapping rows of several solar cells, the electrical voltage can be built up across the rows transverse to the row orientation.

In another approach, the solar elements are first arranged in shingled fashion in so-called strings. In this case, two consecutive solar elements in the longitudinal direction of the string can be glued together in their mutually overlapping shingled arrangement. Here, too, electrically conductive adhesive can be used to electrically connect the solar elements that follow one another in the string. Due to the circuitry created as a result, the voltage is built up in the longitudinal direction of the string via the solar elements of the string. Several strings can then be connected to one another to form a solar module in a string design.

The quality of the solar modules, which are assembled in this way from several solar elements glued together, is influenced, among other things, by the quality of the connection created between the solar elements using the adhesive.

Furthermore, the creation of high-quality adhesive bonds between the solar elements can be associated with comparatively high costs, which can affect the economic efficiency of solar module production.

### SUMMARY

The object of the invention is therefore to provide a device and a method for applying, in particular, electrically conductive adhesive to solar elements, as well as a solar module production device and a method for solar module production, which promote an economical and high-quality production of solar modules.

To solve this object, a method for applying, in particular electrically conductive, adhesive to solar elements is proposed that has one or more of the means and features described herein directed to such a method.

According to the invention, a method for applying, in particular electrically conductive, adhesive to solar elements is proposed to solve the object, wherein a solar element is moved with a workpiece carrier at a defined distance past a dispensing nozzle of a dispensing device for adhesive and adhesive is applied to the solar element in the process. The defined distance at which the solar element is moved past the dispensing nozzle is set before the application of the adhesive using a distance-setting device.

For this purpose, the distance-setting device can produce a setting movement by which the defined distance is set. The setting movement can, for example, be aligned transversely or at right angles to a transfer movement in which the workpiece carrier with the solar element is moved past the dispensing nozzle. The setting movement can be aligned along a dispensing direction of the adhesive onto the solar element, preferably parallel to a dispensing direction predetermined by the dispensing nozzle. In this case, the distance-setting device can move the dispensing nozzle and/or the workpiece carrier and/or a surface along which the workpiece carrier is moved past the dispensing nozzle, by executing the setting movement transversely or at right angles to the transfer movement of the solar element past the dispensing nozzle and/or along the, preferably parallel to the, predefined dispensing direction of the adhesive onto the solar element, in order to set the defined distance.

The defined distance can, in particular, be a distance that can be measured in the dispensing direction of the adhesive onto the solar element between the dispensing nozzle and the solar element in the application position.

The distance from which the adhesive is applied to the solar element can have a significant influence on the adhesive application. Depending on the distance at which the solar element is moved past the dispensing nozzle for the application of adhesive, the adhesive application can, for example, result in thicker or thinner traces.

The invention makes use of the fact that the adhesive application can be influenced in a targeted and comparatively simple manner by specifically adjusting the distance at which the solar element is guided past the dispensing nozzle for the application of adhesive.

Since the distance between the dispensing nozzle and the solar element can be varied using the distance-setting device, it is possible to change the application of adhesive to the solar element independently of the dispensing nozzle and to adjust the method for the application of adhesive quickly and easily if necessary. If, for example, it turns out that the adhesive is being applied in tracks that are too wide or too thick, the distance can be increased by means of the setting movement without having to laboriously modify the device.

In one embodiment of the method, it is provided that the distance-setting device is intended to move the dispensing nozzle and/or the workpiece carrier and/or a surface along which the workpiece carrier is moved past the dispensing nozzle in the setting movement in order to set the defined distance. The dispensing nozzle and/or the workpiece carrier and/or a surface, along which the workpiece carrier is moved past the dispensing nozzle, can be moved in a setting movement that is transverse or perpendicular to the transfer movement of the workpiece carrier and/or along, preferably parallel to, the dispensing direction of the adhesive onto the solar element, as defined by the dispensing nozzle, in order to adjust the defined distance as desired.

Preferably, the adhesive, in particular an electrically conductive adhesive, is applied directly to a busbar of the solar element.

In a preferred embodiment of the method, which will be explained in more detail below, a magnetically driven slider of a magnetically guided planar drive is used as the workpiece carrier. Such a workpiece carrier makes it possible to carry out the setting movement, which is aligned transversely to the transfer movement, in a particularly simple and flexible way and thus promotes a particularly efficient execution of the claimed method.

By setting a defined distance at which the solar element is moved past the dispensing nozzle for the application of adhesive, the freedom of design for the application of adhesive to solar elements can be increased in a particularly simple manner. For example, if it is determined that the adhesive application at a particular distance between the dispensing nozzle and the solar element does not result in the formation of an adhesive trace of a required quality or shape on the solar element, the distance-setting device and the setting movement can be used to adjust the distance at which the solar element is moved past the dispensing nozzle for the application of adhesive in the transfer movement.

The method thus allows efficient adaptation of the process of applying adhesive to a solar element without having to modify the device.

In one embodiment of the method, the workpiece carrier is positioned against a guide by the distance-setting device, in particular by the setting movement, in particular by executing the aforementioned setting movement. Subsequently, the workpiece carrier is moved along the guide and the solar element is moved past the dispensing nozzle at the defined distance. The adhesive is then applied to the solar element.

The guide can be designed in such a way that it forces the workpiece carrier into a path of movement that is arranged relative to the dispensing nozzle in such a way that a solar element located on the workpiece carrier can be moved past the dispensing nozzle at the defined distance. The guide can thus at least indirectly specify the defined distance at which the solar element is moved past the dispensing nozzle for the application of adhesive.

The workpiece carrier can be positioned, in particular by executing the aforementioned setting movement, for example against a guide that is arranged or formed between the dispensing nozzle and a transfer movement plane of the workpiece carrier.

With the distance-setting device, the workpiece carrier is brought closer to the dispensing nozzle, or more precisely to the level at which the dispensing nozzle is arranged, in its setting movement, with the guide limiting the setting movement of the workpiece carrier. As soon as the workpiece carrier makes contact with the guide, the distance-setting device can end the setting movement and the workpiece carrier can be moved past the dispensing nozzle in a transfer movement that is then aligned transversely to the setting movement.

In particular, the setting movement and the transfer movement can be aligned at right angles to one another. In one embodiment of the method, the setting movement is aligned in or against the direction of gravity and/or along a dispensing direction, in particular parallel thereto, of the adhesive onto the solar element. The transfer movement is preferably aligned horizontally.

In one embodiment of the method, the workpiece carrier can be positioned against the guide with a side facing the dispensing nozzle by means of the distance-setting device, in particular by executing the setting movement. However, it is also possible to position the workpiece carrier against the guide with a side facing away from the dispensing nozzle by means of the distance-setting device, in particular by executing the setting movement.

In this variant of the method, the workpiece carrier can be positioned by the distance-setting device against a guide which is arranged or formed on a side of a transfer movement plane of the carrier facing away from the dispensing nozzle. Specifically, the guide can be arranged or formed on a surface along which the workpiece carrier is moved past the at least one dispensing nozzle for the application of adhesive to the solar element. Thus, for applying the adhesive to the solar element, the workpiece carrier can be guided along the guide and between the guide and the dispensing nozzle past the dispensing nozzle. In this variant of the method, the workpiece carrier is moved away from the dispensing nozzle by the distance-setting device.

In one embodiment of the method, a mechanical guide is used as the guide. In another embodiment of the method, a pneumatic guide is used, in particular an air cushion generated by an air bearing unit. A mechanical guide can set the defined distance particularly precisely. The advantage of a pneumatic guide can be that different defined distances can be set comparatively easily. When using an air cushion as a pneumatic guide, it is possible, for example, to make the air cushion correspondingly larger or smaller by changing the air pressure provided by the air bearing unit, in particular with a measurable smaller or larger height in the direction of delivery of the adhesive, and thereby to set the defined distance in the desired way.

The setting movement caused by the distance-setting device and executed by the workpiece carrier is limited by the correspondingly formed air cushion, and the desired distance is set in this way, in which the solar element is carried forward with the workpiece carrier in the transfer movement for the application of adhesive at the dispensing nozzle.

A measurable actual distance between the dispensing nozzle and the solar element in the direction of application of the adhesive can be determined using a distance sensor, and if the actual distance deviates from the defined distance, a setting movement effected by the distance-setting device can be carried out accordingly to set the defined distance. This embodiment of the method allows for automatic adjustment of the defined distance, in which any existing distance deviations are automatically detected and corrected by a targeted execution of the setting movement, so that the solar element for applying adhesive can be automatically moved past the dispensing nozzle at the defined distance from the dispensing nozzle that is correct for the respective application.

In one embodiment of the method, it is provided that the workpiece carrier with the solar element is moved past the dispensing nozzle from below for the application of adhesive to the solar element. The direction of dispensing of the adhesive onto the solar element then corresponds to the direction of gravity. This method variant promotes a particularly precise and simple application of adhesive to the solar element.

The adhesive can preferably be applied to the solar element in the form of an adhesive bead aligned in the direction of a transfer movement of the workpiece carrier past the dispensing nozzle and/or with a lateral offset to a longitudinal center axis of the solar element. Adhesive application of this kind can promote the reliable connection between neighboring solar elements in the solar module that at least partially overlap each other.

In particular, if an electrically conductive adhesive is used, the application of the adhesive in the form of an adhesive bead to the solar element promotes reliable electrical contacting of solar elements that at least partially overlap one another in the solar element.

To solve the object, a method for producing a solar module is also proposed, in which, in particular, electrically conductive adhesive is applied to solar elements according to the method for applying adhesive according to one or more of the features described herein, and the solar elements are then glued together, in particular overlapping one another, to produce the solar module.

By gluing the solar elements to one another, a mechanical and/or electrical connection of the solar elements to one another can be created. Several solar elements coated with adhesive can be arranged in rows. Rows of several solar elements adjacent to one another in the solar module can be glued to one another in a shingled arrangement, overlapping one another, and thereby electrically and mechanically connected to one another.

In this way, a row of solar elements coated with adhesive can be placed on an already laid row of solar elements coated with adhesive in partial overlap and thereby electrically and/or mechanically connected to the laid row.

Two rows arranged next to one another in the solar module to be produced can be arranged with an offset to one another and glued together. This makes it possible to manufacture a so-called shingled matrix solar module, which has particularly good yield values even when part of its photovoltaically effective area is shaded.

Offsets can be used to create an offset of adjacent and/or overlapping rows of solar elements in the solar module. Offsets can be solar elements that have a different, in particular shorter, dimension, measurable in the longitudinal direction of the row of solar elements, compared to the solar elements that are predominantly present within a row.

To solve the object, a device for applying adhesive, in particular electrically conductive adhesive, is also proposed, which has one or more of the means and features described herein directed to such a device. To solve the object, a device for applying adhesive, in particular electrically conductive adhesive, to solar elements is thus proposed, wherein the device has means by which the device is set up to carry out a method for applying adhesive according to one of the claims directed to such a device.

The device can comprise as means for carrying out the method a dispensing device for dispensing, in particular, electrically conductive adhesive having at least one dispensing nozzle, a workpiece carrier for at least one solar element and a feed device with which the workpiece carrier having at least one solar element arranged thereon can be moved in a transfer movement past the at least one dispensing nozzle of the dispensing device. Furthermore, the device can have a distance-setting device that is set up to set a defined distance in which at least one solar element can be moved past the at least one dispensing nozzle with the workpiece carrier to apply adhesive to the solar element.

The workpiece carrier can have at least one receptacle for a solar element. The receptacle can be formed on a side of the workpiece carrier that faces the at least one dispensing nozzle when applying adhesive to the solar element.

The distance-setting device can be set up to carry out a setting movement and, in particular, to move the dispensing nozzle and/or the workpiece carrier and/or a surface of the feed device along which the workpiece carrier can be moved past the at least one dispensing nozzle in the setting movement, in order to set the defined distance.

The distance-setting device can be set up to carry out a setting movement that is oriented transversely or at right angles to a transfer movement plane of the workpiece carrier past the dispensing nozzle and/or along a dispensing direction, in particular parallel to a dispensing direction predetermined by the dispensing nozzle, of the adhesive in order to set the defined distance.

The device can also have at least one guide against which the workpiece carrier can be positioned by the distance-setting device and along which the workpiece carrier, together with at least one solar element arranged thereon, can be moved past the dispensing nozzle. The guide can be arranged or embodied in a dispensing region of the dispensing device, within which the at least one dispensing nozzle of the dispensing device is arranged or embodied.

In one embodiment of the device, it has as a guide a mechanical guide and/or, at least some of the time, a pneumatic guide, in particular an air cushion. To form a pneumatic guide, in particular an air cushion, the device can have an air bearing unit.

The device can have at least one guide that is arranged or formed between a transfer plane of the workpiece carrier and the at least one dispensing nozzle of the dispensing device. The transfer movement plane of the workpiece carrier is the plane within which the workpiece carrier is moved past the dispensing nozzle of the dispensing device for the application of adhesive to a solar element.

In one embodiment of the device, it has a guide that is arranged or formed on one side of the transfer movement plane of the workpiece carrier facing away from at least one dispensing nozzle. The guide can, for example, be formed or arranged on a surface along which the workpiece carrier can be moved past the at least one dispensing nozzle of the dispensing device.

In one embodiment of the device, it is provided that the workpiece carrier comprises, on its side facing the guide, at least one spacer, by means of which the workpiece carrier can be positioned against the guide.

The spacer can serve as a sliding element with which the workpiece carrier makes contact with the respective guide. If the spacer is arranged or designed on a side of the workpiece carrier on which the at least one receptacle for at least one solar element is also arranged or designed, the spacer can also ensure that a minimum distance is maintained between the guide and a solar element arranged on the workpiece carrier. In this way, the spacer can be used to prevent unintentional contact between the solar element and the guide.

The at least one spacer can be arranged on a side of the workpiece carrier on which the at least one solar element can be arranged. The at least one spacer can have a height, measurable in the dispensing direction of the adhesive onto the solar element, which is greater than the height, measurable in the same direction above the workpiece carrier, of a solar element arranged on the workpiece carrier. This can prevent contact between a guide and a solar element arranged on the workpiece carrier.

The guide can comprise at least one guide bar. The guide bar can be aligned in the direction of the transfer movement of the workpiece carrier. If the guide bar of the guide is contacted by the workpiece carrier or a spacer of the workpiece carrier, the guide bar can be designed as a sliding guide bar. The workpiece carrier is then moved in the transfer movement with a sliding contact along the at least one guide bar past the at least one dispensing nozzle of the dispensing device. The workpiece carrier can be guided particularly precisely and securely against tipping if the guide comprises two parallel guide bars that are spaced apart and also aligned in the direction of the transfer movement.

The aforementioned air bearing unit can have at least one air outlet opening. Air can be blown in through the air outlet opening to form an air cushion. Preferably, at least one row of air outlet openings is provided, which is aligned in the direction of a transfer movement of the workpiece carrier past the at least one dispensing nozzle.

The at least one air outlet opening can be formed on an air bearing strip of the air bearing unit. In one embodiment of the air bearing unit, this can comprise at least two air bearing strips, preferably aligned parallel to one another, each having a row of air outlet openings aligned in the direction of the transfer movement. By blowing compressed air through these air outlet openings, an air cushion can be formed which is then arranged between the respective guide bar and the workpiece carrier. The workpiece carrier can comprise a number of counter-strips corresponding to the number of air bearing strips, the surfaces of which facing the air outlet openings act as air bearing surfaces.

In one embodiment of the device, it is provided that it has at least one distance sensor. The distance sensor can be set up to determine a distance between the at least one dispensing nozzle and a solar element arranged on the workpiece carrier or to determine a distance between the dispensing nozzle and the workpiece carrier. The distance sensor can preferably be set up to determine the distance in the dispensing direction of the adhesive and/or for contactless distance measurement. This avoids contact with the solar element and/or the workpiece carrier during the distance measurement.

The distance-setting device of the device can have a drive with which the dispensing nozzle can be adjusted to carry out the setting movement in order to set the defined distance at which the solar element is to be moved past the dispensing nozzle for the application of adhesive by the transfer movement of the workpiece carrier. In this case, the setting movement can be aligned transversely, in particular at right angles, to a transfer movement that the workpiece carrier performs when it is moved past the dispensing nozzle.

The drive that can be used to adjust the dispensing nozzle can be, for example, a spindle drive. A spindle drive facilitates precise execution of the setting movement of the dispensing nozzle.

In one embodiment of the device, the feed device can comprise a magnetically guided planar drive. In this embodiment of the device, the at least one workpiece carrier can be a magnetically driven slider that can be moved past the at least one dispensing nozzle using the planar drive to apply adhesive to the solar element. The planar drive can be set up for multi-coordinate positioning of the workpiece carrier designed as a slider, preferably in six degrees of freedom. In this way, it is possible to carry out not only the transfer movement of the workpiece carrier designed as a slider, but also the setting movement aligned transversely to it, using the planar drive.

The planar drive can have a drive surface along which the workpiece carrier can be moved, preferably in six degrees of freedom. The use of a planar drive and a workpiece carrier designed as a slider makes it possible to apply the adhesive to solar elements with a high degree of design freedom. This makes it possible to create different application patterns by using corresponding movement patterns that can be driven with the workpiece carrier in the dispensing region of the dispensing device.

Furthermore, it is particularly easy to realize adjustments of the adhesive application and thus the method already explained in detail when using a planar drive and a magnetically driven carriage as the workpiece carrier. The drive surface of the planar drive can be the already mentioned surface along which the workpiece carrier is moved past the at least one dispensing nozzle.

To enable the adhesive to be dispensed onto solar elements under the force of gravity, it may be useful to arrange the at least one dispensing nozzle of the dispensing device above the drive surface of the planar drive.

The planar drive can also function as a distance-setting device, with which the at least one workpiece carrier can be moved to set the defined distance in the setting movement, in particular transversely to its transfer movement. In this embodiment of the device, the workpiece carrier, which is designed as a magnetically driven slider, can be moved closer to or further away from the at least one dispensing nozzle by the setting movement in order to set the defined distance.

The device can also be set up to electrostatically charge the workpiece carrier and thus to fix a solar element to the workpiece carrier without contact. For this purpose, the device can have an electrostatic charging device. With the aid of the electrostatic charging device, the workpiece carrier, in particular a receptacle of the workpiece carrier for a solar element, can be electrostatically charged and the solar element can thereby be fixed to the workpiece carrier in a contactless manner.

The device can also have a control unit that is set up to control the distance-setting device in order to set the defined distance by which the solar element is to be moved on the workpiece carrier past the dispensing nozzle. In this way, the control unit can control the setting movement that is effected by the distance-setting device to set the defined distance.

The control unit can be set up in particular to control the distance-setting device as a function of a deviation of an actual distance, determined with the aforementioned distance sensor, from the defined distance, in order to set the defined distance by moving the solar element on the workpiece carrier past the at least one dispensing nozzle.

Finally, a solar module production device having the features of the claim directed to such a device is also proposed to solve the object. The solar module production device is used to produce solar modules from electrically interconnected solar elements, wherein the solar module production device has at least one device for applying adhesive to solar elements, which has the features of one of the claims directed to such a device.

Furthermore, the solar module production device can have a placement device with which the solar elements provided with adhesive can be arranged in a desired laying pattern and can be glued to one another in a mutually overlapping manner.

### BRIEF DESCRIPTION OF THE DRAWINGS

The invention will be described in more detail below with reference to the exemplary embodiments, but is not limited to these exemplary embodiments. Further exemplary embodiments arise from the combination of the features of one or more claims with each other and/or from the combination of one or more features of the examples.

FIGS. 1-10 show different representations of a first embodiment of a device for applying adhesive to solar elements, wherein the device comprises a feed device with a magnetically guided planar drive and a magnetically driven slider is provided as a workpiece carrier, which can be moved past the dispensing nozzles of a dispensing device of the device shown in FIGS. 1-10 with the planar drive in a transfer movement. The workpiece carrier can be moved in a setting movement against a guide and then moved in a transfer movement oriented transversely thereto along the guide past the dispensing nozzles, wherein the guide is arranged on the dispensing device and above a transfer movement plane of the workpiece carrier.

FIGS. 11-20 show different representations of a second embodiment of a device for applying adhesive to solar elements, which are guided with a workpiece carrier in a transfer movement past dispensing nozzles of a dispensing device for adhesive, wherein the device shown in FIGS. 11-20 comprises two guide bars serving as guides in the dispensing region of the dispensing device, onto which the workpiece carrier designed as the slider of the planar drive of this device can be lowered in a setting movement and then moved along the guide bars in the transfer movement past the three dispensing nozzles of the dispensing device.

FIGS. 21-30 show different representations of a further embodiment of the device for applying adhesive to solar elements, wherein in this device an air cushion is provided as a guide for the workpiece carrier, which can be generated by means of an air bearing unit of the device, wherein the air bearing unit is arranged on the dispensing device of the device.

FIGS. 31-37 show different representations of a further embodiment of the device for applying adhesive to solar elements, which device is characterized by its adhesive dispensing nozzle that is movable in a setting movement that is oriented transversely to the transfer movement of the workpiece carrier and a solar element arranged thereon.

FIGS. 38-44 show a further embodiment of the device for applying adhesive to solar elements, wherein in this device, in comparison to the device shown in FIGS. 31-37, the at least one dispensing nozzle of the dispensing device remains stationary and the setting movement is carried out with the workpiece carrier, which is designed as the slider of the planar drive of this device, transversely to the direction of the transfer movement.

### DETAILED DESCRIPTION

All figures show at least parts of a device for applying adhesive to solar elements 2, each marked with reference sign 1. In the following description, components of the devices 1 that correspond in terms of their functions are given corresponding reference signs, even if their design differs.

The devices 1 each have means by which the devices 1 are set up to carry out the method, already explained above, of applying, in particular electrically conductive, adhesive to solar elements 2.

Each of the devices 1 shown has, as a means for carrying out the method, a dispensing device 3 for dispensing, in particular, electrically conductive adhesive, with at least one dispensing nozzle 4. Some of the devices 1 shown have dispensing devices 3, each with three dispensing nozzles 4. Furthermore, all devices 1 have at least one workpiece carrier 5 with at least one receptacle 6 for a solar element 2, a feed device 7 with which the workpiece carrier 5 with at least one solar element 2 arranged thereon can be moved in a transfer movement past the at least one dispensing nozzle 4 of the dispensing device 3. All devices also have a distance-setting device 8. With the respective distance-setting device 8, a defined distance can be set, in which at least one solar element 2 is moved with the workpiece carrier 5 past the at least one dispensing nozzle 4 and adhesive is applied to the solar element 2.

In each of the devices 1, the defined distance is set by a setting movement, which is effected by the respective distance-setting device 8. The setting movements carried out by the respective distance-setting devices 8 are aligned transversely or at right angles to a transfer movement of the solar elements 2 past the respective dispensing nozzle 4 and along a dispensing direction, i.e., in or against a dispensing direction, in particular parallel to a dispensing direction, predetermined by the respective dispensing nozzle 4, of the adhesive onto the solar elements 2.

The devices 1 for applying adhesive 1 shown in the figures differ in part by the type of their distance-setting device 8 and by the setting movements that are carried out to set the defined distance.

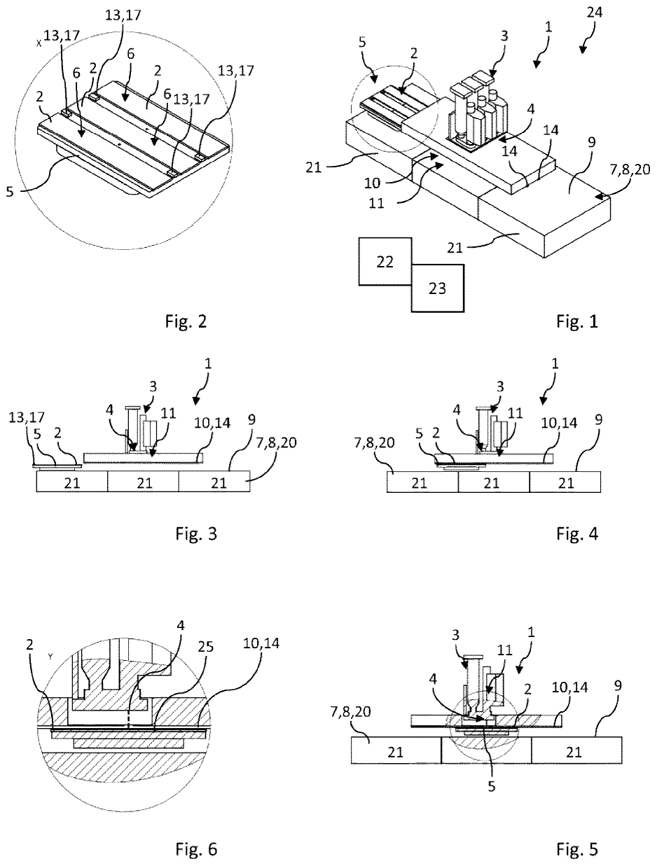

In the embodiments of the device 1 shown in FIGS. 1-10, 11-20, 21-30 and 38-44, the distance-setting device 8 is set up to move the workpiece carrier 5 in a setting movement in order to set the defined distance. In this case, the workpiece carrier 5 is moved in the setting movement transversely or at right angles to its transfer movement, in which it is moved past the dispensing nozzle 4, and thus along a dispensing direction of the adhesive, in particular parallel to a dispensing direction of the adhesive, predetermined by the dispensing nozzle 4.

In the embodiment of the device 1 shown in FIGS. 31-37, the distance-setting device 8 is set up to move the dispensing nozzle 4 of the dispensing device 3 in a setting movement in order to set the defined distance. The dispensing nozzle 4 of the device 1 shown in FIGS. 31-37 is movable in space for this purpose. Again, the setting movement is oriented transversely or at right angles to the transfer movement of the workpiece carrier 5 past the dispensing nozzle 4 and thus along, in particular parallel to, the dispensing direction of the adhesive predetermined by the dispensing nozzle 4.

In an embodiment of the device 1 not shown in the figures, a distance-setting device 8 is provided, which is set up to move a surface 9 of the feed device 7 in a setting movement, along which the workpiece carrier 5 can be moved past the at least one dispensing nozzle 4 to carry out the transfer movement, in order to set the defined distance at which the at least one solar element 2 is moved with the workpiece carrier 5 past the dispensing nozzle 4 of the dispensing device 3 in order to apply adhesive to the solar element 2. This device 1 then has a movable surface 9 of the feed device 7. Here too, the setting movement can be aligned transversely or at right angles to the transfer movement of the workpiece carrier 5 past the dispensing nozzle 4 and thus along the dispensing direction of the adhesive, which is in particular parallel to the dispensing direction predetermined by the dispensing nozzle 4.

The various devices 1 shown in FIGS. 1-30 each have at least one guide 10, which is formed in a dispensing region 11 of the dispensing device 3, within which the at least one dispensing nozzle 4 is arranged.

In the case of these devices 1, the respective workpiece carrier 5 is positioned against the respective guide 10 by the setting movement and then moved along the guide 10 in order to guide the at least one solar element 2 arranged on the workpiece carrier 5 past the dispensing nozzle 4 at the defined distance and to apply adhesive to the solar element 2 in the process.

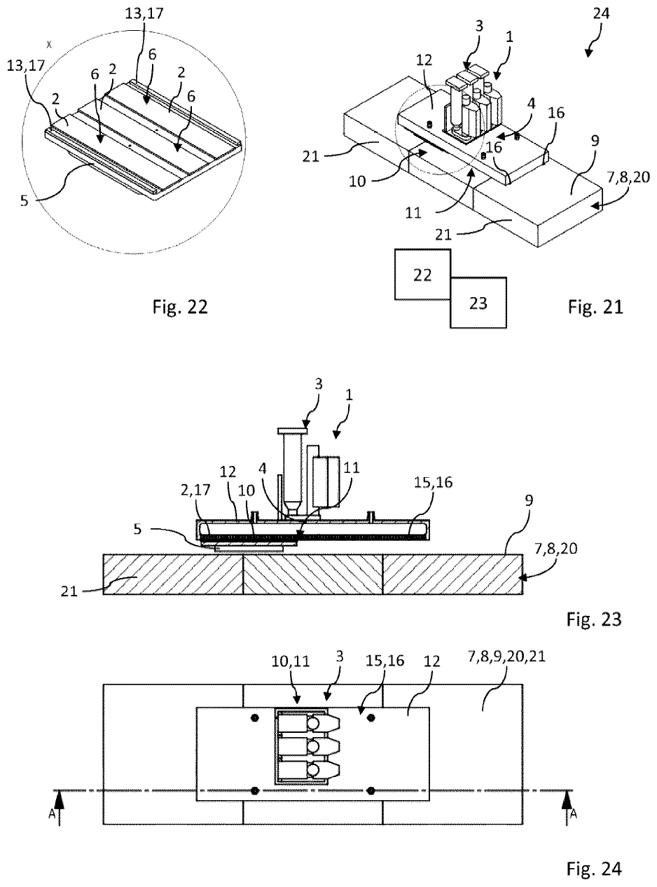

In the two devices 1 shown in FIGS. 1-20, a mechanical guide is used as a guide 10. In the embodiments of the device 1 shown in FIGS. 21-30, a pneumatic guide, namely an air cushion, is used or generated as a guide 10.

To generate the air cushion serving as a pneumatic guide, the device 1 shown in FIGS. 21-30 has an air bearing unit 12.

In the two devices 1 shown in FIGS. 1-10 and 21-30, the guides 10 are each arranged or formed between a transfer plane of movement of the workpiece carrier 5 and the at least one dispensing nozzle 4 of the respective dispensing device 3.

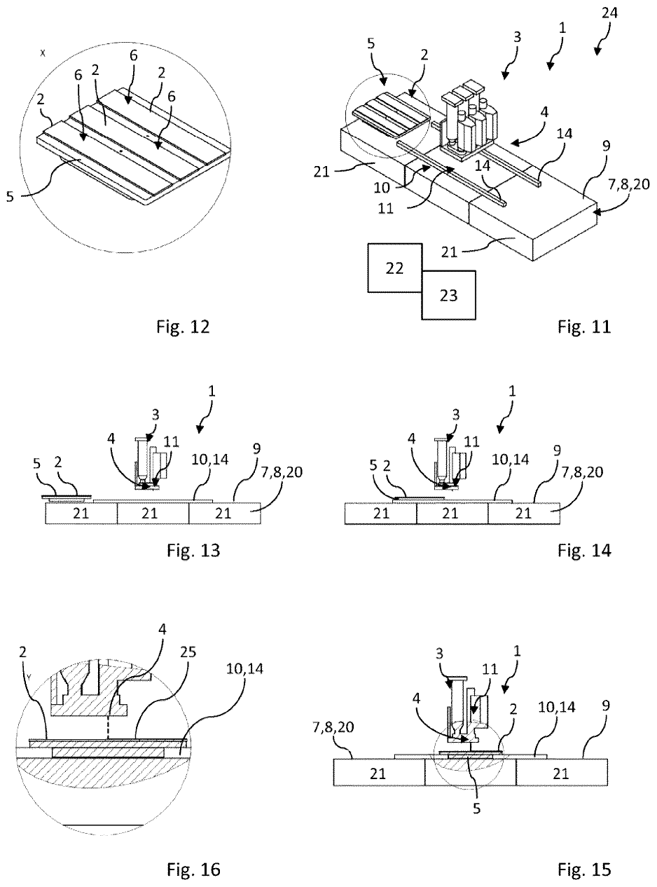

The device 1 shown in FIGS. 11-20 has a guide 10 that is arranged on a side of a transfer movement plane of the workpiece carrier 5 that faces away from the at least one dispensing nozzle 4. This guide 10 is specifically arranged on the previously mentioned surface 9, along which the workpiece carrier 5 is moved past the at least one dispensing nozzle 4 of the dispensing device 3 in order to apply adhesive to the solar element 2 on the workpiece carrier 5.

The devices shown in FIGS. 1-10 and FIGS. 21-30 have workpiece carriers 5 that have spacers 13 on one side of the respective workpiece carrier 5 on which the at least one solar element 2 can be arranged. The spacers 13 have a measurable height in the dispensing direction of the adhesive onto the solar element 2, which is greater than the height, measurable in the same direction, of a solar element 2 arranged on the respective workpiece carrier 5.

The spacers 13 of the workpiece carriers 5 can be seen particularly well in FIG. 2 and in FIG. 22. By means of the setting movement, the workpiece carriers 5 can be positioned with their spacers 13 against the guides 10 and then, in the transfer movement, can be moved along the respective guide 10 past the dispensing nozzles 4.

The devices 1 shown in FIGS. 1-10 and 11-20 have guides 10, each of which comprises two guide bars 14. The guide bars 14 are recognizably aligned in the direction of the transfer movement of the workpiece carrier 5.

In the device 1 shown in FIGS. 1-10, the guide bars 14 are arranged between the dispensing nozzles 4 and the transfer movement plane of the workpiece carrier 5 and on an underside of the dispensing device 3 and extend through the dispensing region 11.

The workpiece carrier 5 can be moved with its four spacers 13 against the guide bars 14 of the guide 10. For this purpose, the workpiece carrier 5 performs the setting movement aligned transversely to the transfer movement, wherein it is brought close to the three dispensing nozzles 4 of the dispensing device 3.

The device 1 shown in FIGS. 11-20 has a guide 10 that has two guide bars 14 oriented parallel to one another and in the direction of the transfer movement. The guide bars of this device 1 are arranged on the surface 9 along which the workpiece carrier 5 is moved past the dispensing nozzles 4 of the dispensing device 3 in the transfer movement.

The setting movement causes the workpiece carrier 5 of the device 1 shown in FIGS. 11-20 to be set down from above on the guide bars 14 of the guide 10 of the device 1 and then guided along the two guide bars 14 at a distance defined by the guide bars 14 past the dispensing nozzles 4. As a result of the setting movement performed by the workpiece carrier 5, the up to three solar elements 2 arranged on the workpiece carrier 3 also reach the defined distance from the dispensing nozzles 4 and can be guided past the dispensing nozzles 4 at the defined distance for the application of adhesive to the solar elements 2.

The air bearing unit 12 of the device 1 shown in FIGS. 21-30 has two rows of air outlet openings 15. The rows of air outlet openings 15 are aligned in the direction of the transfer movement of the workpiece carrier 5. The air outlet openings 15 serve to form an air cushion underneath the air outlet openings 15, which then serves as a guide 10 for the workpiece carrier 5. The rows of air outlet openings 15 extend recognizably through the dispensing region 11 of the dispensing device 3.

The air outlet openings 15 of the air bearing unit 12 are formed on air bearing strips 16 of the air bearing unit 12. The device 1 has two air bearing strips 16 aligned parallel to one another, wherein a row of air outlet openings 15 aligned in the direction of the transfer movement is formed on each of the two air bearing strips 16. The rows of air outlet openings 15 are particularly well recognizable in the sectional view according to FIG. 28.

The workpiece carrier 5 of this device 1, which interacts with the air bearing unit 12, has two counter-strips 17 on its upper side facing the air bearing unit 12, and thus a number of counter-strips 17 corresponding to the number of air bearing strips 16. The counter-strips 17 have surfaces facing the air outlet openings 15. These surfaces of the counter-strips 17 act as air bearing surfaces, with which the workpiece carrier 5 rests against the air cushion, which serves as a guide 10, and slides along it in the transfer movement. In the process, air cushions form between the air outlet openings 15 of the air bearing strips 16 and the counter-strips 17 of the workpiece carrier 5.

At the same time, the counter-strips 17 also perform the function of spacers 13 to protect the solar elements 2, which are arranged on the receptacles 6 of the workpiece carrier 5.

With their already mentioned spacers 13, the other workpiece carriers 5 shown in the figures also have counter-strips 17 that are aligned in the direction of the transfer movement. The various workpiece carriers 5 can make contact with the respective guide 10 by means of their counter-strips 17. The counter-strips 17 then also act as sliding bodies, via which the workpiece carrier 5 is then guided along the respective guide 10 past the dispensing nozzles.

The devices 1 shown in FIGS. 31-44 each have a distance sensor 18. The distance sensors 18 serve to determine an actual distance between the at least one dispensing nozzle 4 and a solar element 2 that is arranged on a receptacle 6 of the respective workpiece carrier 5. The distance sensors 18 are specifically designed to determine the distance between the dispensing nozzle 4 and the solar element 2 in the dispensing direction for adhesive onto the solar element 2 and also for contactless distance measurement.

The device 1 shown in FIGS. 31-37 has a distance-setting device 8 with a drive 19, namely with a spindle drive, with which the dispensing nozzle 4 can be adjusted in space in order to carry out the setting movement transversely to the transfer movement of the workpiece carrier. Taking into account the distance measured by the distance sensor 18, the setting movement can then be carried out in a targeted manner and the dispensing nozzle 4 can be raised or lowered accordingly by means of the drive 19 in order to set the defined distance at which the solar element 2 is to be moved past the dispensing nozzle 4 with the workpiece carrier 5 for the application of adhesive.

All devices 1 have a feed device 7 which comprises a magnetically guided planar drive 20. All workpiece carriers 5 are designed as magnetically driven sliders which can be moved past the at least one dispensing nozzle 4 of the respective dispensing device with the respective planar drive 20 in the transfer movement. The planar drives 20 are each set up for multi-coordinate positioning of the workpiece carriers 5 designed as sliders. The multi-coordinate positioning can take place in up to six degrees of freedom.

Each planar drive 20 has a drive surface as surface 9 along which the respective workpiece carrier 5 can be moved. The drive surface is formed by stators 21 of the respective planar drive 20. In all the devices 1 shown in the figures, the dispensing nozzles 4 of the dispensing devices 3 are each arranged above the drive surface 9 of the respective planar drive 20.

In the embodiments of the devices 1 shown in FIGS. 1-30 and 38-44, the respective planar drive 20 also serves as a distance-setting device 8, by means of which the respective workpiece carrier 5 can be moved transversely to the transfer movement in order to set the defined distance in the setting movement.

All devices 1 also have an electrostatic charging device 22, which is set up to electrostatically charge the workpiece carrier 5 and thus to fix a solar element 2 to the workpiece carrier 5 without contact.

All devices 1 further each comprise a control unit 23 that is configured to control the distance-setting device 8 to execute the setting movement and to set the defined distance by which the solar element 2 is to be moved on the respective workpiece carrier 5 past the at least one dispensing nozzle 4.

In the case of embodiments of the device 1 having distance sensors 18, which are shown in FIGS. 31-44, the control unit 23 is set up to control the distance-setting device 8 depending on a deviation between an actual distance and the defined distance. The actual distance can be a distance that can be measured with the distance sensor 18 between a dispensing nozzle 4 and a solar element 2 arranged on the workpiece carrier 5. The setting movement is then carried out as a function of this deviation in order to set the defined distance at which the solar element 2 is then moved past at least one dispensing nozzle 4 on the workpiece carrier 5.

The device 1 for applying adhesive 1 can be part of a solar module production device, designated as a whole by reference sign 24, which is set up to produce solar modules from electrically interconnected solar elements 2.

The device 1 for applying adhesive to solar elements 2, as explained above, is set up to carry out the method explained below.

In the method for applying, in particular, electrically conductive adhesive to solar elements 2, a solar element 2 is moved past a dispensing nozzle 4 of a dispensing device 3 for adhesive at a defined distance by means of a workpiece carrier 5, and adhesive is applied to the solar element 2 in the process.

Before the adhesive is applied to the solar element 2, the defined distance is set using a distance-setting device 8. For this purpose, a setting movement effected by the distance-setting device 8 is carried out and thereby a defined distance, measurable in the dispensing direction of the adhesive onto the solar element 2, is set, in which the solar element 2 is then moved past the dispensing nozzle 4 for the application of adhesive.

Depending on the embodiment of the method, the distance-setting device 8 causes a setting movement of the dispensing nozzle 4, the workpiece carrier 5 and/or the surface 9, in particular the drive surface of the already mentioned planar drive 20, along which the workpiece carrier 5 is moved past the dispensing nozzle 4, in order to set the defined distance.

In the exemplary embodiments of the method shown in the figures, the setting movement effected by the respective distance-setting device 8 is oriented transversely or at right angles to a transfer movement of the solar elements 2 past the respective dispensing nozzle 4 and also along a, in particular parallel to a, predetermined dispensing direction of the adhesive, through the respective dispensing nozzle 4, onto the solar elements 2.

In the case of the devices 1 that have a guide 10, it is provided according to the method that the workpiece carrier 5 is brought into contact with the respective guide 10 by means of the setting movement and then move the workpiece carrier 5, with at least one solar element 2 arranged thereon, along the guide 10 past the dispensing nozzle 4 and apply adhesive to the solar element 2 in the process.

In the devices 1 shown in FIGS. 1-10 and FIGS. 21-30, the workpiece carrier 5 is positioned by the setting movement against a guide 10 arranged between the dispensing nozzle 4 and a transfer movement plane of the workpiece carrier 5. In the process, the workpiece carrier 5 is moved away from the surface 9 and closer to the dispensing nozzle 4.

In the case of the device 1 shown in FIGS. 11-20, the workpiece carrier 5 is positioned by the setting movement against a guide 10, which is arranged on a side of a transfer movement plane of the workpiece carrier 5 that faces away from the dispensing nozzle 4.

In the embodiments of the devices 1 shown in FIGS. 1-10 and 21-30, the respective workpiece carrier 5 is positioned by the setting movement with a side facing the dispensing nozzle 4 against the guide 10. In the case of the device 1 shown in FIGS. 11-20, it is provided to remove the workpiece carrier 5 from the dispensing nozzle 4 by means of the setting movement and, in doing so, to position it against the guide 10 with a side facing away from the dispensing nozzle.

While the guides 10 shown in FIGS. 1-10 and 11-20 are mechanical guides, a pneumatic guide is provided for the device 1 shown in FIGS. 21-30. In this case, an air cushion is generated as a pneumatic guide by means of the air bearing unit 12 of the device 1.

In the devices 1 shown in FIGS. 31-44, a measurable actual distance in the dispensing direction of the adhesive between the dispensing nozzle 4 and solar element 2 on the respective workpiece carrier 5 is determined using a distance sensor 18, and the setting movement is carried out accordingly if the actual distance deviates from the defined distance in order to set the defined distance in which the solar element 2 is then guided past the dispensing nozzle 4.

In all the embodiments of the device 1 shown, the respective workpiece carrier 5 is guided past the dispensing nozzle 4 underneath the respective dispensing nozzle 4 with at least one solar element 2 for the application of adhesive to the solar element 2. The electrically conductive adhesive is applied in each case in the form of an adhesive bead 25 oriented in the direction of the transfer movement and in the direction of the longitudinal center axis of the solar element 2 to the solar element 2 and with lateral offset to the longitudinal center axis of the respective solar element 2 to the solar element 2. The adhesive beads 25 are preferably applied directly to the busbars of the solar elements 2. This promotes a reliable electrical interconnection in the finished solar module of solar elements 2 that are later glued together.

FIGS. 3-10 illustrate the application of the method for applying adhesive to solar elements, which is carried out on the device 1 shown in FIGS. 1-10.

FIG. 3 shows the workpiece carrier 5 in a starting position. From this starting position, the workpiece carrier 5 is guided, on the one hand, in a transfer movement oriented to the right and, on the other hand, in the setting movement. As a result of the setting movement, the workpiece carrier 5 is lifted by the drive surface 9 and moved closer to the dispensing nozzles 4 of the dispensing device 3. As a result, the workpiece carrier reaches the position shown in FIG. 4, where it contacts the guide bars 14 of the guide 10 with its spacers 13. FIGS. 5 and 6 show the workpiece carrier 5 still in contact with the guide 10, but now moved further to the right, wherein the application of adhesive to the solar elements 2 arranged on the surface of the workpiece carrier 5 can also be seen.

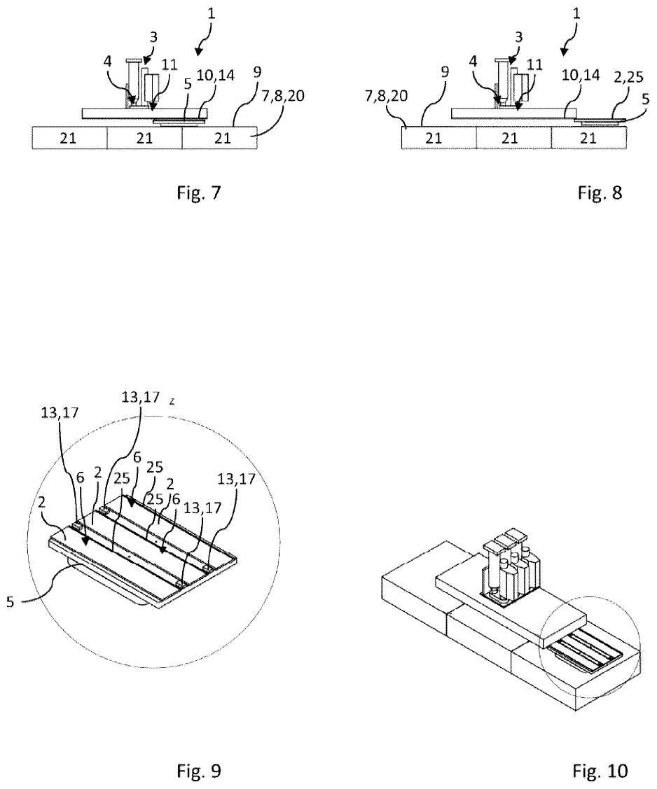

FIG. 7 shows the workpiece carrier 5 after the application of the adhesive to the solar elements 2. In this position, the workpiece carrier 5 has been moved back in the direction of the drive surface 9, i.e. away from the dispensing nozzles 4 by a return movement opposite to the setting movement. FIG. 8 shows the workpiece carrier 5 with the solar elements 2 arranged thereon then outside the dispensing region 11 of the dispensing device 3.

FIGS. 9 and 10 show that each of the three solar elements 2 arranged on the workpiece carrier 5 is coated with an adhesive bead 25. The adhesive beads are applied with a lateral offset to the longitudinal center axes of the solar elements 2 and oriented in the direction of the longitudinal center axes.

FIGS. 13-20 clearly show how the device shown in FIGS. 11-20 works.

In FIG. 13, the workpiece carrier 5 is in a starting position on the drive surface 9 and still outside the dispensing region 11 of the dispensing device 3.

By means of a movement aligned to the right in the image plane, the workpiece carrier 5 is moved into the dispensing region 11 of the dispensing device 3 and, by means of a setting movement aligned transversely thereto, is lowered onto the guide bars 14 of the guide 10 in order to set the defined distance in which the solar elements 2 are then guided past the dispensing nozzles 4 of the dispensing device 3 for the application of adhesive. For this purpose, the workpiece carrier 5 is then guided along the guide bars 14 of the guide 10 past the three dispensing nozzles 4 of the dispensing device 3, as shown in FIGS. 15 to 18. The height of the guide bars 14 above the drive surface 9 then determines the defined distance at which the solar elements 2 are guided past the dispensing nozzles.

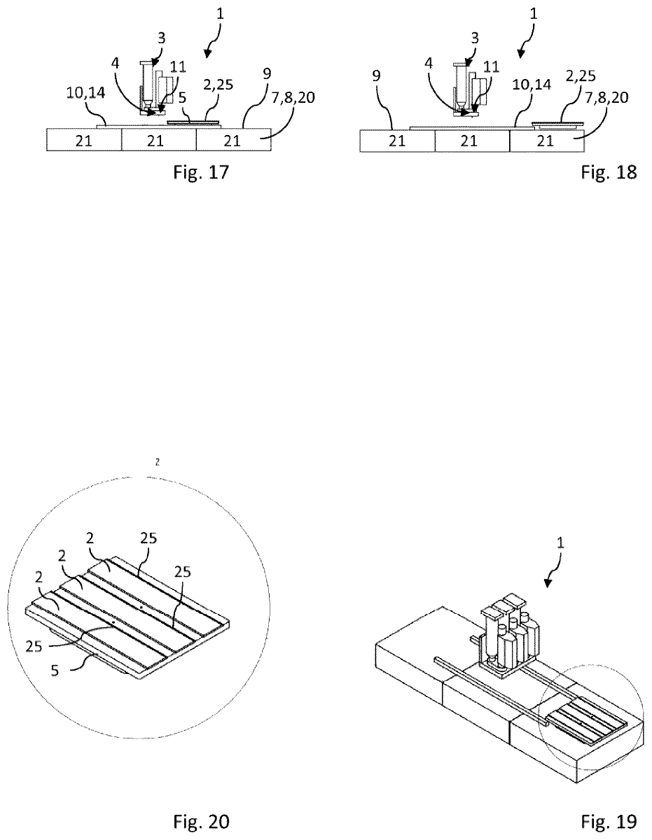

In FIG. 17, the workpiece carrier 5 is shown in a position that it assumes after the application of the adhesive to the solar elements 2. Here, the workpiece carrier 5 is raised by a return movement opposite to the setting movement back to a level that it had before lowering onto the guide bars 14.

FIGS. 19 and 20 show the result of the adhesive application, namely three adhesive beads 25 aligned in the direction of the longitudinal center axes of the respective solar elements 2 and applied in an offset manner with respect to these.

In the device 1 shown in FIGS. 21-30, it is provided to move the workpiece carrier 5 with three solar elements 2 arranged thereon from a starting position through the setting movement from below against air cushions serving as a guide 10, which are generated with the air bearing unit 12 of the device 1.

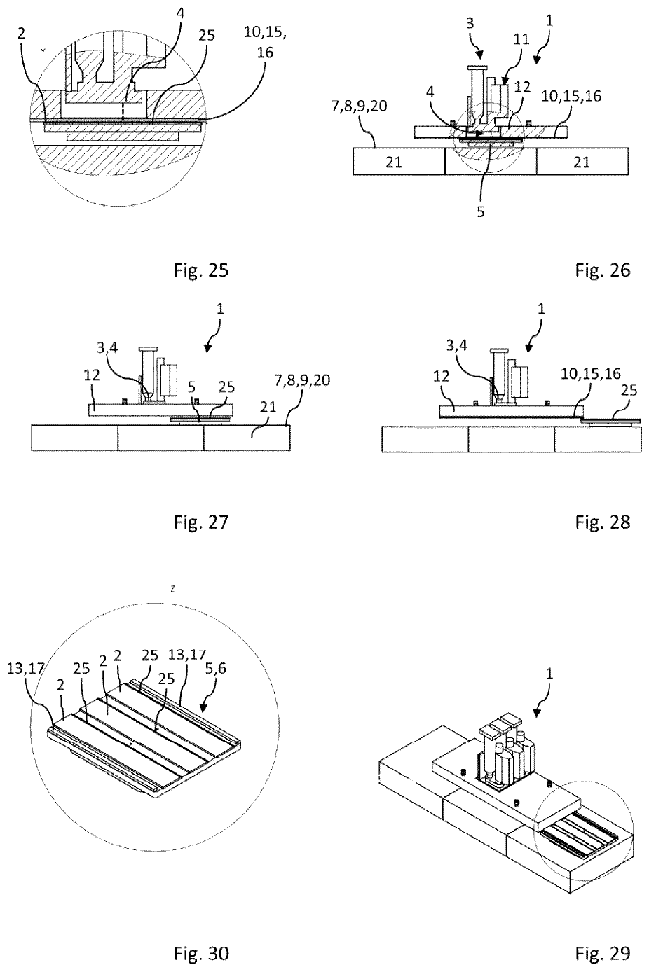

Starting from a starting position not shown, outside the dispensing region 11 of the dispensing device 3, the workpiece carrier 5 is brought to the position shown in FIG. 23. This is done by lifting the workpiece carrier 5 from the drive surface 9 with the help of the planar drive 20 in its function as a distance-setting device 8. FIG. 23 shows the workpiece carrier 5 with its counter-strips 17 in contact with the air cushions serving as a guide 10. From the position shown in FIG. 23, the workpiece carrier 5 with the three solar elements 2 arranged on it is then moved to the position shown in FIGS. 26 and 25. Some of the adhesive has already been applied to the solar elements 2.

According to FIG. 27, the workpiece carrier 5 is then lowered again in a return movement in the direction of the drive surface 9 of the planar drive 20 and then removed from the dispensing region 11 of the dispensing device 3 according to FIG. 28.

FIGS. 29 and 30 show the result of the adhesive application. Each of the three solar elements 2 is provided with an adhesive bead 25, which is arranged in the direction of the longitudinal center axis of the respective solar element 2 and offset to it on the solar element 2.

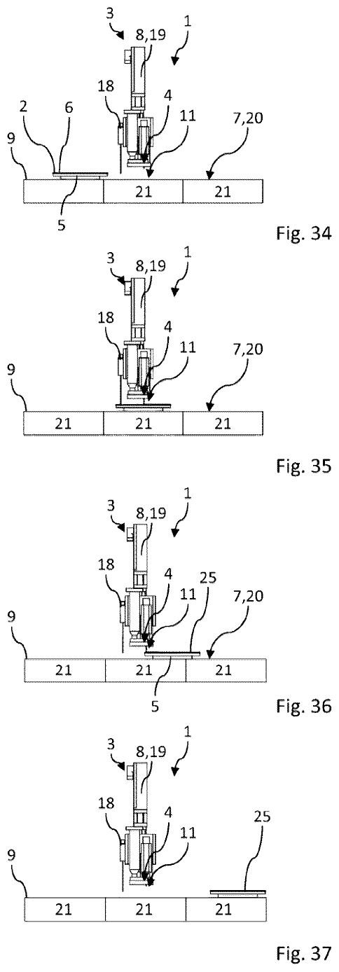

FIGS. 34-37 illustrate the functioning of the device 1 shown in FIGS. 31-37.

From a starting position according to FIG. 34, the workpiece carrier 5 with a solar element 2 arranged thereon is moved into the detection range of the distance sensor 18 of the device 1. The position of the dispensing nozzle 4 in the space is changed depending on the distance determined by the distance sensor 18 between the dispensing nozzle 4 and the solar element 2 positioned on the workpiece carrier 5. This occurs when there is a deviation of the determined distance from the defined distance, in which the solar element 2 is to be moved past the dispensing nozzle 4.

The position of the dispensing nozzle is adjusted by the setting movement of the distance-setting device 8. Depending on the distance deviation, the drive 19, which is designed as a spindle drive, changes the position of the dispensing nozzle 4 above the solar element 2 arranged on the workpiece carrier 5. In this way, the workpiece carrier 5 with the solar element 2 located thereon is guided past at the correct distance from the dispensing nozzle 4, so that the adhesive can be applied as desired.

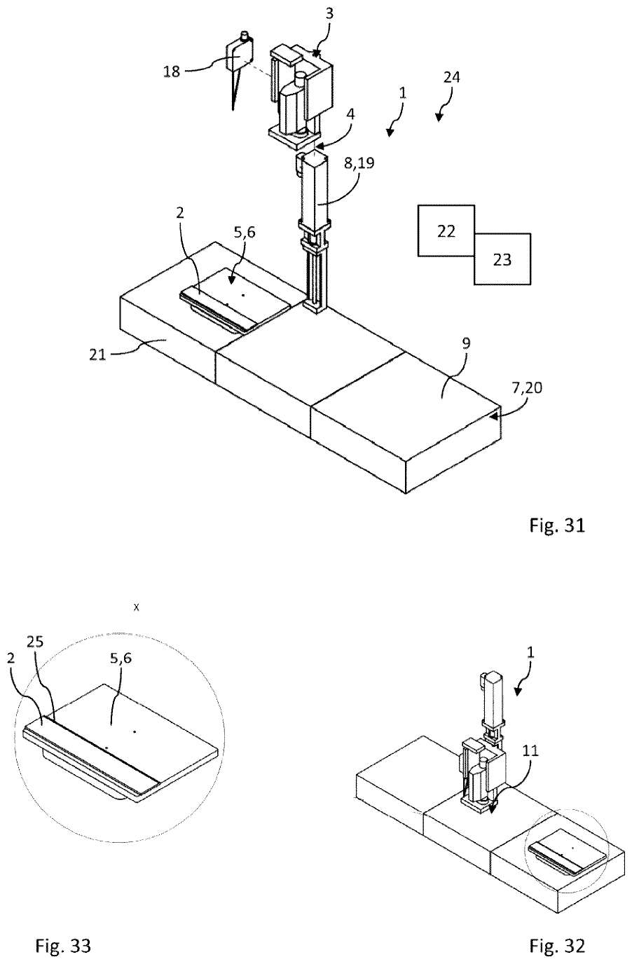

The result of this method is shown in FIGS. 32 and 33. An adhesive bead 25 can be seen on the solar element 2, aligned in the direction of the longitudinal center axis of the solar element 2 and offset with respect to it.

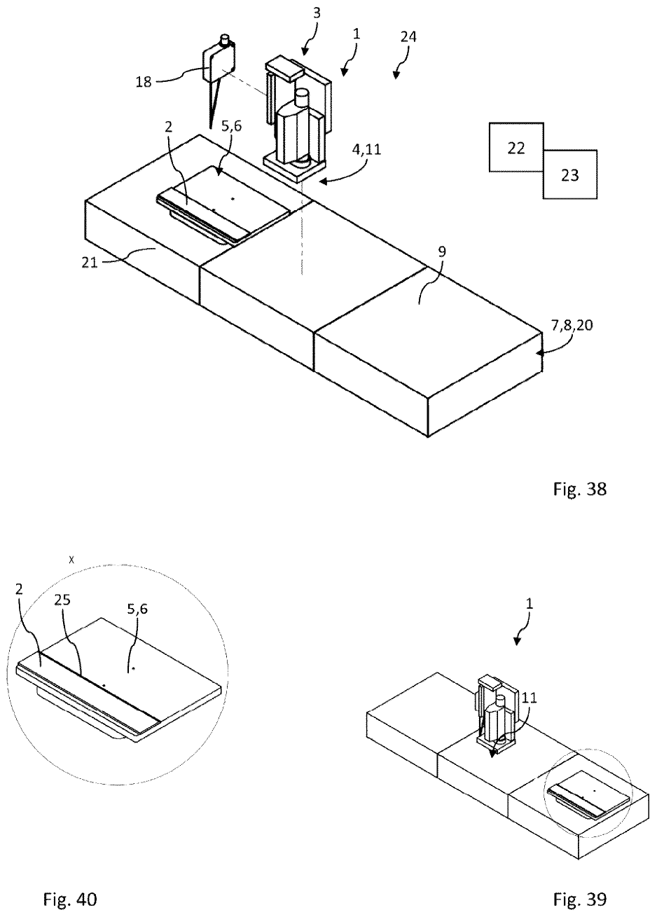

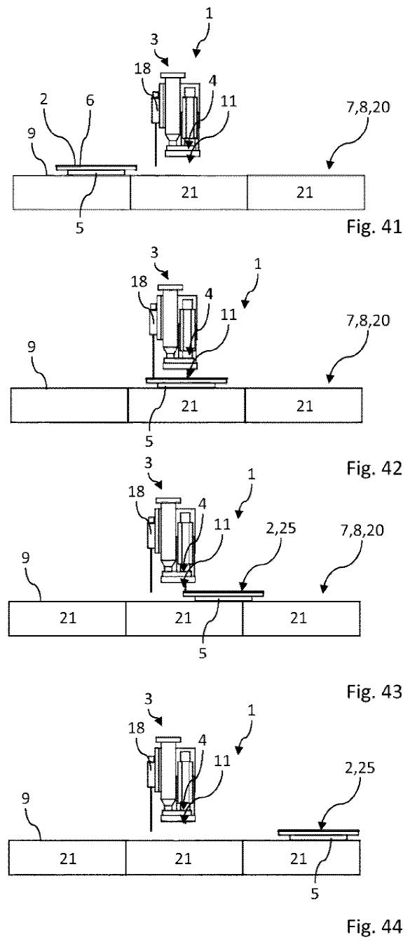

FIGS. 41-44 clearly show how the device 1 shown in FIGS. 38-44 works.

Similar to device 1, which is shown in FIGS. 31-37, the distance between the dispensing nozzle 4 and the solar element 2 is determined by a distance sensor 18 of this device 1. If a deviation between the defined distance, at which the solar element 2 is to be guided past the dispensing nozzle 4, and the determined distance is detected, the distance-setting device 8 causes a corresponding setting movement, by means of which the defined distance can then be set.

In this case, it is provided to adjust the workpiece carrier 5 depending on the determined distance deviation with the planar drive 20 in its function as a distance-setting device 8, i.e. to either approach the workpiece carrier 5 and thus the solar element 2 to the dispensing nozzle 4 or to remove it from it in the setting movement.

FIG. 41 shows the workpiece carrier 5 still outside the dispensing region 11 of the dispensing device 3. As a result of a transfer movement of the workpiece carrier 5 aligned to the right, the solar element 2 arranged on it enters the detection range of the distance sensor 18. The distance between the solar element 2 and the dispensing nozzle 4 of the dispensing device 3 is determined by contactless distance measurement. If a deviation is detected between the determined distance and the defined distance at which the solar element 2 is to pass the dispensing nozzle 4, a distance correction can be carried out. This is done by the distance-setting device 8, namely here the planar drive 20, either raising or lowering the workpiece carrier 5 on the drive surface 9.

FIG. 42 shows the workpiece carrier 5 with the solar element 2 in the dispensing region 11 of the dispensing device 3. The solar element 2 is already positioned below the dispensing nozzle 4 for the application of the adhesive.

According to FIG. 43, the application of the adhesive is almost complete. FIG. 44 shows the workpiece carrier 5 after the adhesive has been applied to the solar element 2 outside the dispensing region 11 of the dispensing device 3.

FIGS. 39 and 40 show the result of the adhesive application. It can be seen that the solar element 2 has an adhesive bead 25 arranged in the longitudinal direction of its longitudinal center axis and offset thereto.

The method for applying adhesive to solar elements 2 can be carried out as part of a method for producing a solar module. In this case, in particular electrically conductive adhesive is applied to solar elements 2 in accordance with the method for applying adhesive to solar elements 2 before the solar elements 2 are then bonded to one another, for example overlapping one another, to produce a solar module.

### List of Reference Signs

1 Device for applying adhesive
2 Solar element
3 Dispensing device
4 Dispensing nozzle
5 Workpiece carrier
6 Receptacle on 5 for 2
7 Feed device
8 Distance-setting device
9 Surface, drive surface
10 Guide
11 Dispensing region
12 Air bearing unit
13 Spacer
14 Guide bar
15 Air outlet opening
16 Air bearing strip
17 Counter-strip
18 Distance sensor
19 Drive, spindle drive
20 Planar drive
21 Stator
22 Electrostatic charging device
23 Control unit
24 Solar module production device
25 Adhesive bead

1. A method for applying, adhesive to solar elements (2), the method comprising:
moving a solar element (2) with a workpiece carrier (5) at a defined distance past a dispensing nozzle (4) of a dispensing device (3) for the adhesive;
applying the adhesive to the solar element (2); and
setting the defined distance at which the solar element (2) is moved past the dispensing nozzle (4) for the application of the adhesive before the application of the adhesive using a distance-setting device (8).

2. The method according to claim 1, wherein the distance-setting device (8) produces a setting movement by which the defined distance is set, in including the distance-setting device (8) moving at least one of the dispensing nozzle (4), the workpiece carrier (5), or a surface (9), along which the workpiece carrier (5) is moved past the dispensing nozzle (4), in the setting movement in order to set the defined distance.

3. The method according to claim 2, wherein the setting movement produced by the distance-setting device (8) is aligned transversely or at right angles to a transfer movement of the solar element (2) past the dispensing nozzle (4) and/or along a dispensing direction.

4. The method according to claim 1, further comprising positioning the workpiece carrier (5) against a guide (10) by the distance-setting device (8) along which the workpiece carrier (5) and thus the solar element (2) is moved at the defined distance for the application of adhesive past the dispensing nozzle (4).

5. The method according to claim 1, further comprising positioning the workpiece carrier (5) by the distance-setting device (8) against a guide (10) arranged or formed between the dispensing nozzle (4) and a transfer movement plane of the workpiece carrier (5).

6. The method according to claim 1, further comprising positioning the workpiece carrier (5) by the distance-setting device (8), against a guide (10) which is arranged or formed on a side of a transfer movement plane of the workpiece carrier (5) facing away from the dispensing nozzle (4).

7. The method according to claim 1, further comprising positioning the workpiece carrier (5) against the guide (10) by the distance-setting device (8) with a side facing the dispensing nozzle (4), or positioning the workpiece carrier (5) against the guide (10) by the distance-setting device (8) with a side facing away from the dispensing nozzle (4).

8. The method according to claim 4, further comprising using a mechanical guide and/or a pneumatic guide as the guide.

9. The method according to claim 1, further comprising determining an actual distance between the dispensing nozzle (4) and the solar element (2), which actual distance is measurable in the dispensing direction of the adhesive, using a distance sensor (18) and, if the actual distance deviates from the defined distance, carrying out a setting movement effected by the distance-setting device (8) accordingly in order to set the defined distance.

10. The method according to claim 1, further comprising at least one of a) the moving of the workpiece carrier (5) with the solar element (2) past the dispensing nozzle (4) for the application of adhesive to the solar element (2) is carried out below the dispensing nozzle (4), and/or b) applying the adhesive to the solar element (2) as an adhesive bead (25) aligned in a direction of a transfer movement of the workpiece carrier (5), or c) applying the adhesive to the solar element (2) with a lateral offset with respect to a longitudinal center axis of the solar element (2).

11. A method for producing a solar module, comprising: applying electrically conductive adhesive to solar elements (2) according to the method for applying adhesive according to claim 1, and gluing the solar elements (2) to produce the solar module.

12. A device (1) for applying adhesive to solar elements (2), the device (1) comprising:
a workpiece carrier (5) adapted to carry a solar element (2) at a defined distance past a dispensing nozzle (4) for the adhesive;
a distance-setting device (8) for setting a defined distance at which the solar element (2) is moved past the dispensing nozzle (4) for the application of the adhesive before the application of the adhesive; and
wherein the device (1) is set up to carry out the method for applying the adhesive to the solar elements (2) according to claim 1.

13. The device (1) according to claim 12, further comprising a dispensing device (3) for dispensing the adhesive with at least one said dispensing nozzle (4), and a feed device (7) by which the workpiece carrier (5) having at least one of the solar elements (2) arranged thereon is adapted to be moved past the at least one dispensing nozzle (4) of the dispensing device (3).

14. The device (1) according to claim 13, wherein the distance-setting device (8) is configured to carry out a setting movement, in which the distance-setting device (8) is set up to move at least one of the dispensing nozzle (4), the workpiece carrier (5), or a surface (9) of the feed device (7) along which the workpiece carrier (5) is to be moved past the at least one dispensing nozzle (4) in the setting movement, in order to set the defined distance.

15. The device (1) according to preceding claim 14, wherein the distance-setting device (8) is configured to carry out a setting movement that is oriented transversely or at right angles to a transfer movement plane of the workpiece carrier (5) past the dispensing nozzle (4) and/or along a dispensing direction of the adhesive in order to set the defined distance.

16. The device (1) according to claim 12, further comprising at least one guide (10) in a dispensing region (11) of the dispensing device (3), within which the at least one dispensing nozzle (4) is arranged or formed, and the workpiece carrier (5) is adapted to be positioned against the at least one guide (10) by the distance-setting device (8) and along which the workpiece carrier (5), together with a solar element (2) arranged thereon, are adapted be moved past the dispensing nozzle (4).

17. The device (1) according to claim 16, wherein the guide (10) is a mechanical guide and/or a pneumatic guide.

18. The device (1) according to claim 17, wherein the at least one guide (10) comprises at least one air bearing unit (12) that is set up to form a pneumatic guide.

19. The device (1) according to claim 12, further comprising at least one of a) at least one guide (10) which is arranged or formed between a transfer plane of the workpiece carrier (5) and the at least one dispensing nozzle (4) of the dispensing device (3), or b) a guide (10) arranged or formed on one side of a transfer movement plane of the workpiece carrier (5) facing away from the at least one dispensing nozzle (4).

20. The device according to claim 16, wherein the workpiece carrier (5) has at least one spacer (13) on a side thereof facing the guide (10), by which the workpiece carrier (5) is adapted to be positioned against the guide (10).

21. The device (1) according to claim 20, wherein the at least one spacer (13) is arranged on a side of the workpiece carrier (5) on which the at least one solar element (2) is adapted be arranged, and/or the at least one spacer (13) has a height, measurable in the dispensing direction of the adhesive onto the solar element (2), which is greater than a height, measurable in the same direction, of the solar element (2) arranged on the workpiece carrier (5).

22. The device according to claim 16, wherein the guide (10) has at least one guide bar (14).

23. The device according to claim 16, wherein the guide has at least one air outlet opening (15) aligned in the direction of a transfer movement of the workpiece carrier (5) past the at least one dispensing nozzle (4), for forming an air.

24. The device (1) according to claim 12, wherein the workpiece carrier (5) has a counter-strip (17) on a side thereof facing the guide (10).

25. The device (1) according to claim 12, further comprising at least one distance sensor (18) for determining a distance between the at least one dispensing nozzle (4) and the solar element (2) arranged on the at least one workpiece carrier (5).

26. The device (1) according to claim 12, wherein the distance-setting device (8) has a drive (19) with which the dispensing nozzle (4) is adapted to be adjusted to carry out the setting movement.

27. The device (1) according to claim 13, wherein the feed device (7) comprises a magnetically guided planar drive (20) and the at least one workpiece carrier (5) is a magnetically driven slider that is adapted to be moved past the at least one dispensing nozzle (4) using the planar drive (20) in order to apply adhesive to the solar element (2).

28. The device (1) according to claim 27, wherein the planar drive (20) is set up for multi-coordinate positioning of the workpiece carrier (5) designed as a slider, and/or the planar drive (20) has a drive surface (9) on which the workpiece carrier (5) is adapted to be moved, preferably in six degrees of freedom.

29. The device (1) according to claim 28, wherein the at least one dispensing nozzle (4) of the dispensing device (3) is arranged above the drive surface (9) of the planar drive (20).

30. The device (1) according to claim 28, wherein the planar drive (20) functions as the distance-setting device (8), with which the at least one workpiece carrier (5) is adapted to be moved transversely to the transfer movement in the setting movement in order to set the defined distance.

31. The device (1) according to claim 12, further comprising an electrostatic charging device (22) which is set up to electrostatically charge the workpiece carrier (5) to fix the solar element (2) to the workpiece carrier (5) without contact.

32. The device (1) according to claim 25, further comprising a control unit (23) which is set up to control the distance-setting device (8), as a function of a deviation between the defined distance and an actual distance measured by the distance sensor (18), in order to set the defined distance by moving the solar element (2) on the workpiece carrier (5) past the at least one dispensing nozzle (4).

33. A solar module production device (24) for producing solar modules from electrically interconnected solar elements (2), wherein the solar module production device (24) comprises the device (1) according to claim 12 for applying adhesive to the solar elements (2).
